(19) United States
(12) Patent Application Publication
(10) Pub. No.: US 2008/0241421 A1
(43) Pub. Date: Oct. 2, 2008

(54) OPTOELECTRONIC DEVICE AND METHOD OF FABRICATING THE SAME

(75) Inventors: MIIN JANG CHEN, Taipei City (TW); YING TSANG SHIH, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Miin Jang CHEN, Taipei City (TW)

(21) Appl. No.: 12/060,602

(22) Filed: Apr. 1, 2008

(30) Foreign Application Priority Data
Apr. 2, 2007 (TW) 096111647

(51) Int. Cl. C23C 16/513; B05D 5/12; B32B 9/04

(52) U.S. Cl. 427/576; 427/126.4; 427/126.3; 428/221; 257/79; 257/E33.002

(57) ABSTRACT

The invention provides an optoelectronic device and the fabrication thereof. The method according to the invention, firstly, prepares a substrate. Then, the method forms a multi-layer structure on the substrate. Afterward, by an atomic layer deposition based process, the method forms a passivation layer overlaying the multi-layer structure.

### BACKGROUND OF THE INVENTION

1. Field of the Invention

The invention relates to an optoelectronic device and method of fabricating the same, and more particularly, to an optoelectronic device and fabrication method which forms a passivation layer by an atomic layer deposition based process.

2. Description of the Prior Art

Along with the rapid development of optoelectronic industry, versatile optoelectronic devices such as light-emitting diodes, laser diodes, photo-detectors, and solar cells, are extensively used in many fields of applications. Moreover, with the progress of the optoelectronic technologies, required performance of properties, such as light emission efficiency and optoelectronic conversion efficiency, are as well getting higher and higher.

Generally speaking, forming a passivation layer on the surface of an optoelectronic device can improve, to some extent, some properties of the optoelectronic device, such as light emission efficiency and optoelectronic conversion efficiency. For example, an efficient silicon light-emitting diode traditionally uses a thermal oxide as the surface passivation layer. To produce this, the fabrication method supplies oxygen to the silicon wafer at high temperature such that the surface of the silicon wafer is oxidized to generate the passivation layer of silicon dioxide. The passivation layer formed on the surface of the silicon light-emitting diode can provide surface passivation effect on the silicon light-emitting diode, so as to improve light emission efficiency of the silicon light-emitting diode.

However, traditionally produced passivation layers usually have some flaws such as poor thickness control, insufficient coverage, or high defect density. Such poor-quality passivation layers do not help a lot in improving the properties of the optoelectronic devices.

Furthermore, the processing temperature at which the oxide layers are formed is often up to several hundred, or even over one thousand degrees Celsius. The over-high processing temperature could destroy the prepared structure of the optoelectronic device, or cause the malfunction and/or damage of the equipment, so as to lower the reliability of the process and equipment availability.

Accordingly, a scope of the invention is to provide an optoelectronic device and method of fabricating the same to solve aforesaid problems.

### SUMMARY OF THE INVENTION

A scope of the invention is to provide an optoelectronic device and method of fabricating the same. The method is to form a passivation layer overlaying a multi-layer structure of the optoelectronic device by an atomic layer deposition based process.

According to an embodiment of the invention, the method of fabricating an optoelectronic device, firstly, prepares a substrate. Then, the method forms a multi-layer structure on the substrate. Finally, the method forms a passivation layer overlaying the multi-layer structure by an atomic layer deposition based process.

Therefore, according to the invention, the method of fabricating an optoelectronic device forms a passivation layer overlaying the multi-layer structure by an atomic layer deposition based process. Thereby, the passivation layer can provide excellent surface passivation effect, so as to enhance the performance of the optoelectronic device. Furthermore, since the processing temperature is relatively low, destruction of the prepared structure of the optoelectronic device can be avoided, and the damage and/or malfunction probability of equipment owing to high temperature can be reduced, such that the reliability of the process and the equipment availability are further enhanced.

The advantage and spirit of the invention may be understood by the following recitations together with the appended drawings.

### BRIEF DESCRIPTION OF THE APPENDED DRAWINGS

FIG. 1 shows the fabrication method according to an embodiment of the invention.

FIG. 2A through FIG. 2D shows the table of the composition of the passivation layer and precursors thereof.

FIG. 3 shows L-I (optical power vs. injection current) curves of two optoelectronic devices.

FIG. 4 shows the photoluminescence spectra of three optoelectronic devices.

FIG. 5 shows the comparison of light emission efficiencies of three optoelectronic devices.

FIG. 6 shows the relationship between the photoluminescence light emission intensities and the excitation intensities of two optoelectronic devices.

### DETAILED DESCRIPTION OF THE INVENTION

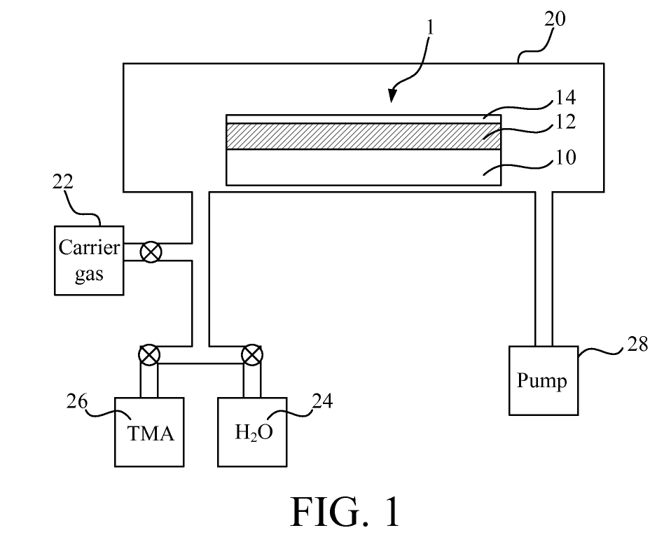

Please refer to FIG. 1. FIG. 1 shows the fabrication method according to an embodiment of the invention. The fabrication method according to an embodiment of the invention is used for fabricating an optoelectronic device 1. In actual applications, the optoelectronic device 1 can be an organic light-emitting diode, an organic solar cell, an inorganic light-emitting diode, an inorganic solar cell, a photo-detector, a laser diode, or the like.

As shown in FIG. 1. The method, firstly, prepares a substrate 10. Then, the method forms a multi-layer structure 12 on the substrate 10. In the embodiment, the substrate 10 can be a sapphire substrate, a Si substrate, a SiC substrate, a GaN substrate, AlGaN substrate, a InGaN substrate, a ZnO substrate, a ScAlMgO₄ substrate, a YSZ (yttria-stabilized zirconia) substrate, a SrCu₂O₂ substrate, a CuAlO₂ substrate, LaCuOS substrate, a NiO substrate, a LiGaO₂ substrate, a LiAlO₂ substrate, a GaAs substrate, a InP substrate, a glass substrate, or so on. The multi-layer structure 12 can include, preferable but not limited to, a PN-junction, a hetero-junction, a quantum well, a quantum wire, a quantum dot, a superlattice, a nanorod, a nanotube, a nanowire, a nanoparticle. In actual applications, the substrate 10 can be, but not limited to, a patterned substrate.

Then, the substrate 10 along with the multi-layer structure 12 are set in a reaction chamber 20 designed for performing an atomic layer deposition (ALD) based process.

Thereafter, by an atomic layer deposition based process, the method forms a passivation layer 14 overlaying the multi-layer structure 12. In actual applications, the atomic layer deposition based process can be an atomic layer deposition process, a plasma-enhanced atomic layer deposition process, a plasma-assisted atomic layer deposition process, or combination thereof, such as combination of the atomic layer deposition process and the plasma-enhanced atomic layer deposition process or combination of the atomic layer deposition process and the plasma-assisted atomic layer deposition process. Using the plasma-enhanced ALD process or the plasma-assisted ALD process can ionize precursors, so as to lower the processing temperature and to improve the processing quality. It is noticeable that the atomic layer deposition process is also named as Atomic Layer Epitaxy (ALE) process or Atomic Layer Chemical Vapor Deposition (ALCVD) process, so that these processes are actually the same.

In an embodiment, the passivation layer 14 can be further annealed at a temperature ranging from 100° C. to 1200° C. after deposition.

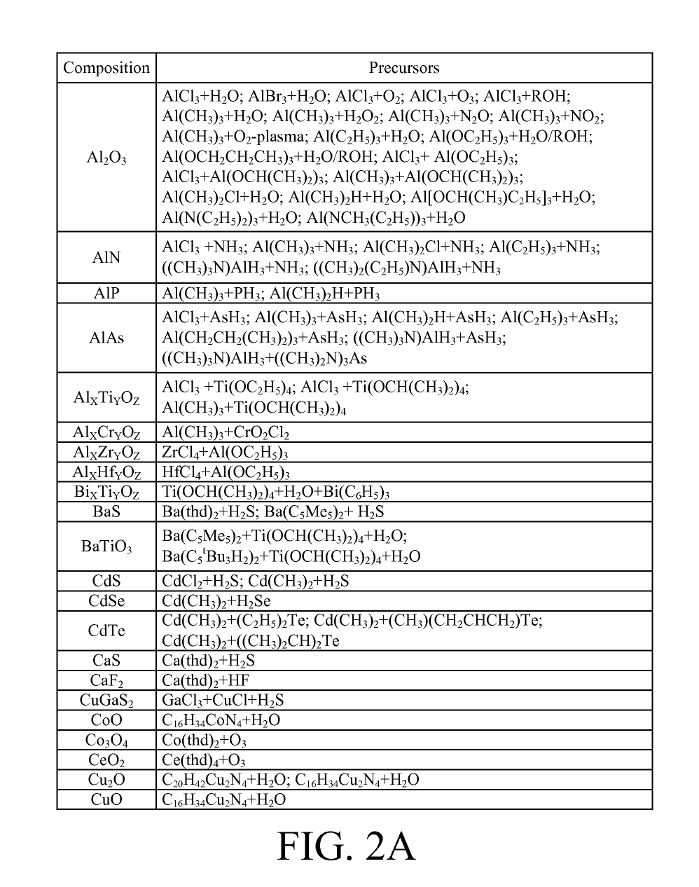

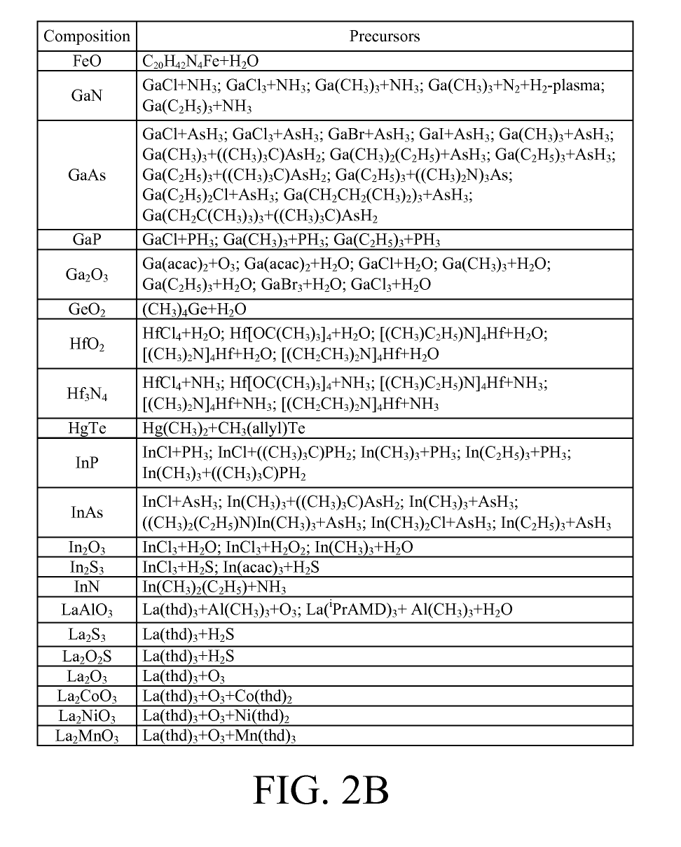

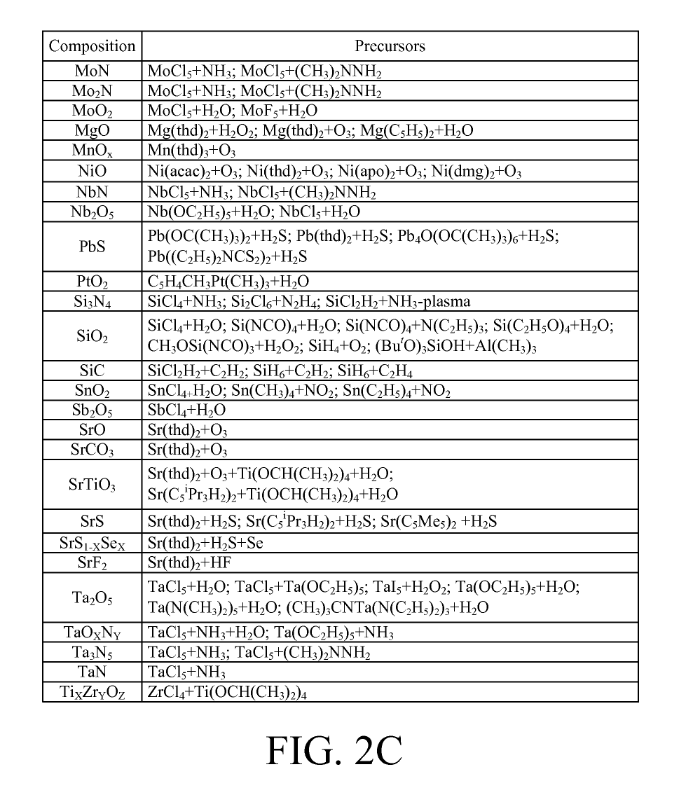

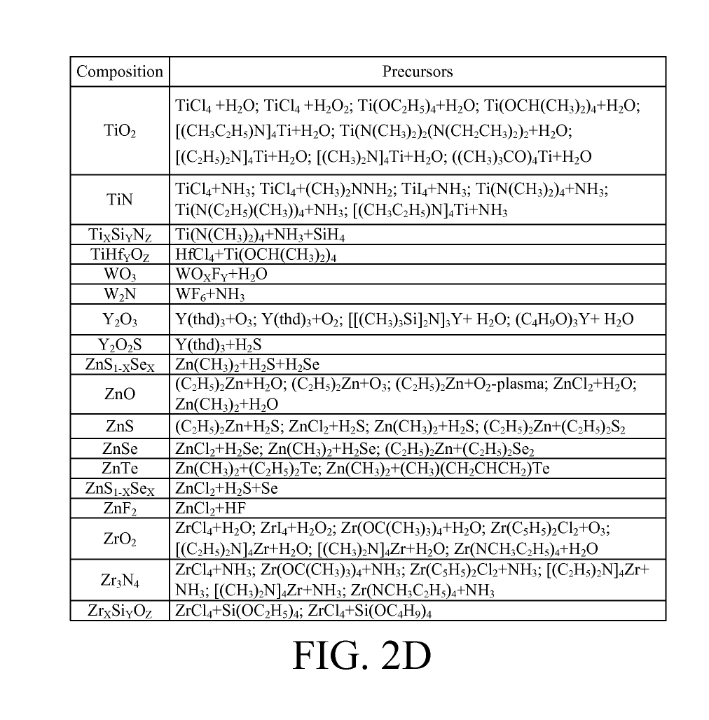

Please refer to FIG. 2A through 2D. FIG. 2A through 2D shows the table of the composition of the passivation layer 14 and precursors thereof. In an embodiment, the composition of the passivation layer 14 can be Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, CuO, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnO_{X}, NiO, NbN, Nb₂O₅, PbS, PtO₂, Si₃N₄, SiO₂, SiC, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS_{1-X}Se_{X}, ZnO, ZnS, ZnSe, ZnTe, ZnS_{1-X}Se_{X}, ZnF₂, ZrO₂, Zr₃N₄, Zr_{X}Si_{Y}O_{z}, or so on, or mixture thereof.

In the table shown in FIG. 2A through 2D, thd is 2,2,6,6,-tetramethyl-3,5-heptanediode. Alkaline earth and yttrium thd-complexes used may also contain a neutral adduct molecule or they may have been slightly oligomerized. Further, acac is acetyl acetonate; iPr is CH(CH₃)₂; Me is CH₃; tBu is C(CH₃)₃; apo is 2-amino-pent-2-en-4-onato, dmg is dimethylglyoximato; (ButO)₃SiOH is tris(tert-butoxy)silanol (((CH₃)₃CO)₃SiOH); La(iPrAMD)₃ is tris(N,N′-diisopropylacetamidinato)lanthanum.

As shown in FIG. 1, an example of forming an Al₂O₃ thin film by an atomic layer deposition process is presented. In an embodiment, an atomic layer deposition cycle (ALD cycle) includes four reaction steps of:
1. Using a carrier gas 22 to carry H₂O molecules 24 into the reaction chamber 20; thereby, the H₂O molecules 24 are absorbed on the surface of the multi-layer structure 12 to form a layer of OH radicals.
2. Using the carrier gas 22, with assistance of the pump 28, to purge the H₂O molecules 24 which are not absorbed on the surface of the multi-layer structure 12.
3. Using the carrier gas 22 to carry TMA (Trimethylaluminum) molecules 26 into the reaction chamber 20; thereby, the TMA molecules 26 react with the OH radicals absorbed on the surface of the multi-layer structure 12 to form one monolayer of Al—O radicals, where a by-product is organic molecules.
4. Using the carrier gas 22, with assistance of the pump 28, to purge the residual TMA molecules 26 and the by-product due to the reaction.

In the embodiment, the carrier gas 22 can be highly pure argon gas or nitrogen gas. The above four steps is called one ALD cycle. One ALD cycle grows a thin film with a thickness of only one monolayer on the entire surface of the multi-layer structure 12; the characteristic is named as “self-limiting”, and the characteristic allows the precision of the thickness control of the atomic layer deposition to be one monolayer. Therefore, the thickness of the deposited layer can be precisely controlled by the number of ALD cycles.

In the embodiment, the processing temperature is in a range of from room temperature to 600° C. It is noticeable that since the processing temperature is relatively low, destruction of the prepared structure of the optoelectronic device can be avoided, and the damage and/or malfunction probability of equipment owing to high temperature can be reduced, such that the reliability of the process and the equipment availability are further enhanced.

The passivation layer formed by an atomic layer deposition based process has following advantages:
1. Excellent conformality and good step coverage.
2. Precise thickness control, to the degree of one monolayer.
3. Low defect density and pinhole-free structures.
4. Low deposition temperatures.
5. Accurate control of material composition.
6. Abrupt interface and excellent interface quality.
7. High uniformity.
8. Good process reliability and reproducibility.
9. Large-area and large-batch capacity.

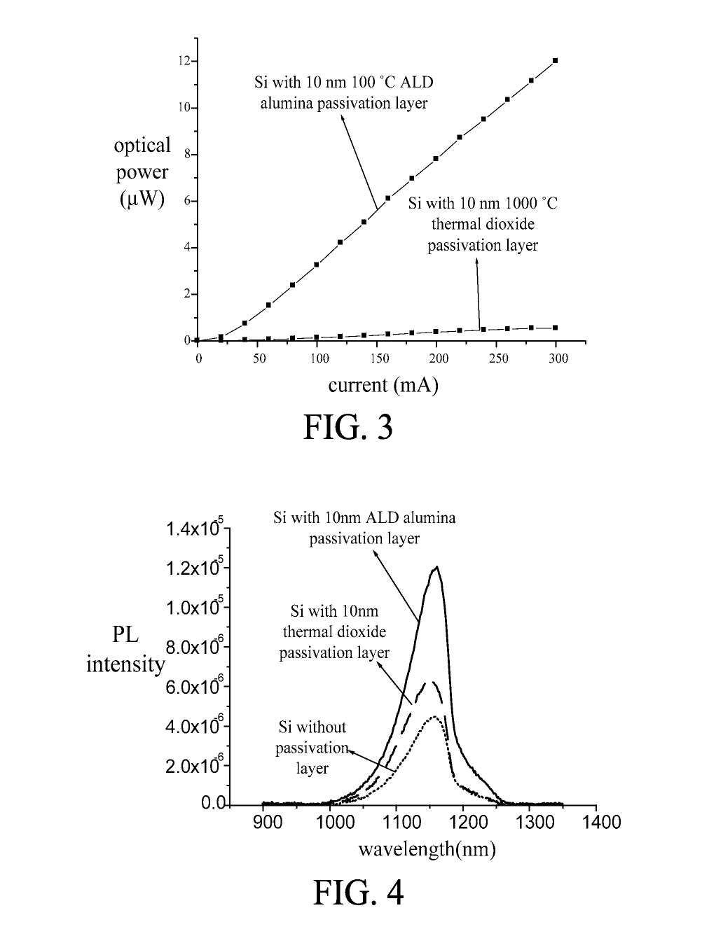

Please refer to FIG. 3. FIG. 3 shows L-I (optical power vs. injection current) curves of two optoelectronic devices. An optoelectronic device A (not shown) and an optoelectronic device B are both metal-insulator-semiconductor silicon light-emitting diodes. The optoelectronic device A has an alumina (Al₂O₃) passivation layer of 10 nm thickness formed by an ALD process. The optoelectronic device B has a silicon oxide passivation layer of 10 nm thickness formed at the processing temperature of 1000° C. As shown in FIG. 3, the light emission efficiency of the optoelectronic device A with the alumina passivation layer is one order of magnitude higher than that of the optoelectronic device B.

Please refer to FIG. 4. FIG. 4 shows the photoluminescence (PL) spectra of three optoelectronic devices. As shown in FIG. 4, at room temperature, the light emission intensity of the optoelectronic device A with the alumina passivation layer is obviously stronger than that of the optoelectronic device B with silicon dioxide and the device without surface passivation layer.

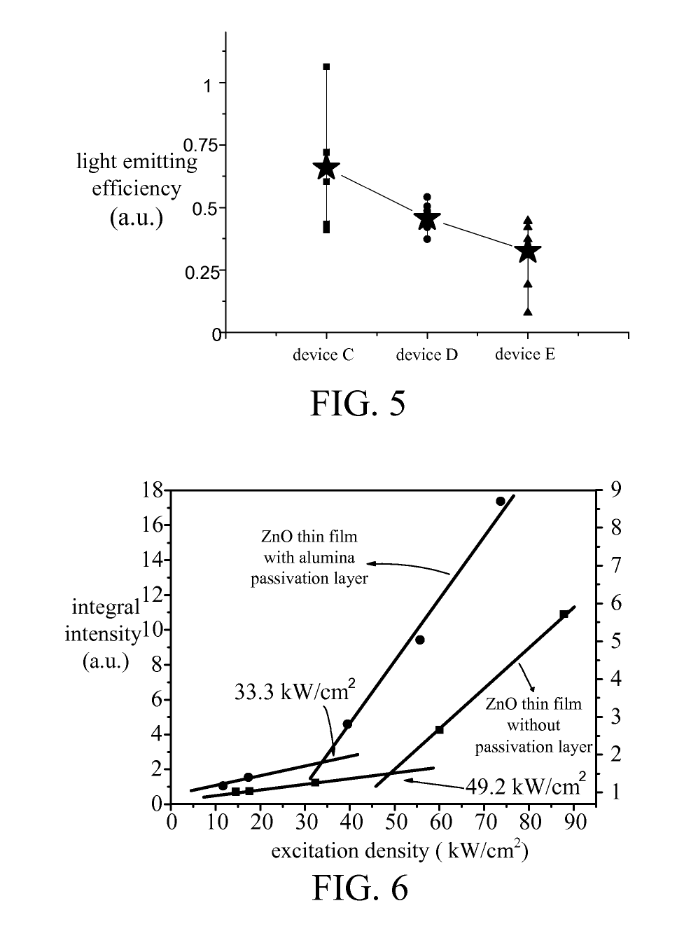

Please refer to FIG. 5. FIG. 5 shows the comparison of light emission efficiencies of three optoelectronic devices. An optoelectronic device C (not shown), an optoelectronic device D (not shown) and an optoelectronic device E (not shown) are all PN-junction silicon light-emitting diodes. The optoelectronic device C has an alumina passivation layer of 10 nm thickness formed by an ALD process. The optoelectronic device D has a silicon oxide passivation layer of 10 nm thickness formed at the processing temperature of 1000° C. The optoelectronic device E has no surface passivation layer. As shown in FIG. 5, the light emission efficiency of the optoelectronic device C with the alumina passivation layer is higher than that of the optoelectronic device D and the optoelectronic device E.

Please refer to FIG. 6. FIG. 6 shows the relationship between the photoluminescence light emission intensities and the excitation intensities of two optoelectronic devices. An optoelectronic device F and an optoelectronic device G are both ZnO optoelectronic thin films. The optoelectronic device F has an alumina passivation layer formed by an ALD process. The optoelectronic device G has no surface passivation layer. As shown in FIG. 6, stimulated emission threshold of the optoelectronic device F with the alumina passivation layer is 33.3 kW/cm²; and the threshold of the optoelectronic device G without passivation layer is 49.2 kW/cm². Accordingly, the alumina passivation layer formed by the ALD process can improve the light emission efficiency of the ZnO optoelectronic film to some extent.

Comparing with prior arts, the method of fabricating an optoelectronic device according to the invention forms passivation layer overlaying the multi-layer structure by an atomic layer deposition based process. Since the passivation layer formed by the atomic layer deposition based process has advantages such as excellent conformality, precise thickness control, low defect density, low deposition temperature, accurate control of material composition, abrupt interface and excellent interface quality, high uniformity, good process reliability and reproducibility, and large-area and large-batch capacity, etc., the passivation layer can provide excellent surface passivation effect, so as to enhance the performance of optoelectronic devices. Furthermore, since the processing temperature is relatively low, destruction of the prepared structure of the optoelectronic device can be avoided, and the damage and/or malfunction probability of equipment owing to high temperature can be reduced, such that the reliability of the process and the equipment availability are further enhanced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of fabricating an optoelectronic device, comprising the steps of:
preparing a substrate;
forming a multi-layer structure on the substrate; and
by an atomic layer deposition based process, forming a passivation layer overlaying the multi-layer structure.

2. The method of claim 1, wherein the atomic layer deposition based process comprises at least one selected from a group consisting of an atomic layer deposition process, a plasma-enhanced atomic layer deposition process and a plasma-assisted atomic layer deposition process.

3. The method of claim 1, wherein the passivation layer is formed at a processing temperature ranging from room temperature to 600° C.

4. The method of claim 1, wherein the passivation layer is further annealed at a temperature ranging from 100° C. to 1200° C. after deposition.

5. The method of claim 1, wherein the optoelectronic device is one selected from the group consisting of an organic light-emitting diode, an organic solar cell, an inorganic light-emitting diode, an inorganic solar cell, a photo-detector, and a laser diode.

6. The method of claim 1, wherein the multi-layer structure comprises one selected from the group consisting of a PN-junction, a hetero-junction, a quantum well, a quantum wire, a quantum dot, a superlattice, a nanorod, a nanotube, a nanowire, and a nanoparticle.

7. The method of claim 1, wherein the substrate is one selected from the group consisting of a sapphire substrate, a Si substrate, a SiC substrate, a GaN substrate, AlGaN substrate, a InGaN substrate, a ZnO substrate, a ScAlMgO₄ substrate, a YSZ (yttria-stabilized zirconia) substrate, a SrCu₂O₂ substrate, a CuAlO₂ substrate, LaCuOS substrate, a NiO substrate, a LiGaO₂ substrate, a LiAlO₂ substrate, a GaAs substrate, a InP substrate, and a glass substrate.

8. The method of claim 1, wherein the substrate is a patterned substrate.

9. The method of claim 1, wherein the composition of the passivation layer comprises at least one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, CuO, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnOₓ, NiO, NbN, Nb₂O₅, PbS, PtO₂, Si₃N₄, SiO₂, SiC, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS_{1-X}Se_{X}, ZnO, ZnS, ZnSe, ZnTe, ZnS_{1-X}Se_{X}, ZnF₂, ZrO₂, Zr₃N₄, and Zr_{X}Si_{Y}O_{Z}.

10. An optoelectronic device, comprising:
a substrate;
a multi-layer structure formed on the substrate; and
a passivation layer formed by an atomic layer deposition based process and overlaying the multi-layer structure.

11. The optoelectronic device of claim 10, wherein the atomic layer deposition based process comprises at least one selected from a group consisting of an atomic layer deposition process, a plasma-enhanced atomic layer deposition process and a plasma-assisted atomic layer deposition process.

12. The optoelectronic device of claim 10, wherein the passivation layer is formed at a processing temperature ranging from room temperature to 600° C.

13. The optoelectronic device of claim 10, wherein the passivation layer is further annealed at a temperature ranging from 100° C. to 1200° C. after deposition.

14. The optoelectronic device of claim 10, wherein the multi-layer structure comprises one selected from the group consisting of a PN-junction, a hetero-junction, a quantum well, a quantum wire, a quantum dot, a superlattice, a nanorod, a nanotube, a nanowire, and a nanoparticle.

15. The optoelectronic device of claim 10, wherein the substrate is one selected from the group consisting of a sapphire substrate, a Si substrate, a SiC substrate, a GaN substrate, AlGaN substrate, a InGaN substrate, a ZnO substrate, a ScAlMgO₄ substrate, a YSZ (yttria-stabilized zirconia) substrate, a SrCu₂O₂ substrate, a CuAlO₂ substrate, LaCuOS substrate, a NiO substrate, a LiGaO₂ substrate, a LiAlO₂ substrate, a GaAs substrate, a InP substrate, and a glass substrate.

16. The optoelectronic device of claim 10, wherein the substrate is a patterned substrate.

17. The optoelectronic device of claim 10, wherein the composition of the passivation layer comprises at least one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, CuO, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnOₓ, NiO, NbN, Nb₂O₅, PbS, PtO₂, Si₃N₄, SiO₂, SiC, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS_{1-X}Se_{X}, ZnO, ZnS, ZnSe, ZnTe, ZnS_{1-X}Se_{X}, ZnF₂, ZrO₂, Zr₃N₄, and Zr_{X}Si_{Y}O_{Z}.
